(19) United States
(12) Patent Application Publication
(10) Pub. No.: US 2023/0221755 A1
(43) Pub. Date: Jul. 13, 2023

(54) ELECTRONIC DEVICE WITH LOW POWER SENSING DEVICE USING DYNAMIC CLOCK MODULATION

(71) Applicant: SAMSUNG ELECTRO-MECHANICS CO., LTD., Suwon-si (KR)

(72) Inventors: Joo Yul KO, Suwon-si (KR); Byung Joo HONG, Suwon-si (KR); Joo Hyoung LEE, Suwon-si (KR); Gwang Pyo PARK, Suwon-si (KR)

(73) Assignee: SAMSUNG ELECTRO-MECHANICS CO., LTD., Suwon-si (KR)

(21) Appl. No.: 17/714,262

(22) Filed: Apr. 6, 2022

(30) Foreign Application Priority Data
Jan. 7, 2022 (KR) 10-2022-0002963

(51) Int. Cl. G06F 1/12; G06F 1/10; G06F 1/324

(52) U.S. Cl. CPC G06F 1/12; G06F 1/10; G06F 1/324

(57) ABSTRACT

A low power sensing device includes a sensor including key sensors configured to generate sensing signals, respectively, a reference sensor configured to generate a reference sensing signal, a two-state clock generator configured to generate a first clock signal and a second clock signal having clock frequencies different from each other, and a controller. The controller is configured to receive the sensing signals and the reference sensing signal, control enable operations and disable operations of the sensor and the reference sensor based on a first operation mode and a second operation mode each repeatedly performed for a predetermined time, receive the first clock signal during the first operation mode, and receive the second clock signal during the second operation mode.

### CROSS-REFERENCE TO RELATED APPLICATION(S)

This application claims the benefit under 35 USC 119(a) of Korean Patent Application No. 10-2022-0002963 filed on Jan. 7, 2022 in the Korean Intellectual Property Office, the entire disclosure of which is incorporated herein by reference for all purposes.

### BACKGROUND

### 1. Field

The present disclosure relates to an electronic device with a low power sensing device using a dynamic clock modulation.

### 2. Description of Related Art

Electronic devices such as mobile phones typically use mechanical button switches instead of keyless sensing devices including touch switches.

As keyless sensing devices become more prevalent in electronic devices, there is a desire to use the keyless sensing device for gaming phones requiring quicker responses to a key.

A conventional mechanical button switch may consume current of several tens of uA, whereas the touch switch included in the keyless sensing device may consume more current than the conventional mechanical button switch, and may consume current of several mA or more.

The conventional button switch not for the gaming phone may have a short usage time and low frequency, whereas the touch switch for the gaming phone may be always operated in many cases, and thus be desired to save power to be used in the gaming phone.

A conventional keyless sensing device may reduce power consumption as follows: the keyless sensing device may be operated in a full power mode and then switched to a standby mode when there is no key input, thus maintaining low power consumption, may wake up when a predetermined condition is satisfied and perform an operation to be switched back to an operation mode, and may repeatedly perform the operation mode and the standby mode.

However, when including a gaming mode, the conventional keyless sensing device is unable to perform the standby mode while maintaining a gaming operation, thus significantly increasing power consumption.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a low power sensing device includes a sensor including key sensors configured to generate sensing signals by sensing touch or press activity, respectively, a reference sensor configured to generate a reference sensing signal, a two-state clock generator configured to generate a first clock signal and a second clock signal having clock frequencies different from each other, and a controller. The controller is configured to receive the sensing signals and the reference sensing signal, control enable operations and disable operations of the sensor and the reference sensor based on a first operation mode and a second operation mode each repeatedly performed for a predetermined time, receive the first clock signal during the first operation mode, and receive the second clock signal during the second operation mode.

The controller may be further configured to control the enable operations during the first operation mode, and the disable operations during the second operation mode.

The controller may be further configured to hold data of each of the key sensors that is output in an enabled state during the first operation mode from being output in a disabled state during the second operation mode.

The controller may be configured to put the reference sensor in an enabled state before the key sensors, and in a disabled state simultaneously or later than the key sensors.

The controller may be configured to synchronize the two-state clock generator with the first operation mode or the second operation mode to alternate between the first clock signal with a high clock frequency and the second clock signal with a low clock frequency.

The two-state clock generator may be further configured to alternate between the first clock signal and the second clock signal using a current control method to reduce glitches.

The frequencies of the first clock signal and the second clock signal for an external interface may be several megahertz (MHz).

The low power sensing device may further include a low power clock generator configured to function as a wake-up timer in a sleep mode, and generate a low power time clock.

In another general aspect, an electronic device includes touch members positioned in a housing formed on a side of the electronic device, a sensor including key sensors positioned to correspond to the touch members, and configured to generate sensing signals based on touches or presses input through the corresponding touch members, a reference sensor configured to generate a reference sensing signal, a two-state clock generator configured to generate a first clock signal and a second clock signal having clock frequencies different from each other, and a controller. The controller is configured to enable operations and disable operations of the sensor and the reference sensor, receive the first clock signal during a first operation mode, and receive the second clock signal during a second operation mode, based on the first operation mode and the second operation mode each repeatedly performed for a predetermined time.

The controller may be further configured to control the enable operations of the sensor and the reference sensor during the first operation mode, and the disable operations of the sensor and the reference sensor during the second operation mode.

The controller may be further configured to hold data of each of the key sensors that is output in an enabled state during the first operation mode from being output in a disabled state during the second operation mode.

The controller may be configured to put the reference sensor in an enabled state earlier than the key sensors of the sensor, and in a disabled state simultaneously or later than the key sensors.

The controller may be configured to synchronize the two-state clock generator with the first operation mode or the second operation mode to alternate between the first clock signal having a high clock frequency and the second clock signal having a low clock frequency.

The two-state clock generator may be further configured to alternate between the first clock signal and the second clock signal using a current control method to reduce glitches.

The frequencies of the first clock signal and the second clock signal for an external interface may be several megahertz (MHz).

The electronic device may further include a low power clock generator configured to function as a wake-up timer in a sleep mode, and generate a low power time clock.

Other features and aspects will be apparent from the following detailed description, the drawings, and the claims.

### BRIEF DESCRIPTION OF DRAWINGS

FIG. 1 is a view showing an example of a low power sensing device according to one or more embodiments of the present disclosure.

FIG. 2 is a view showing another example of the low power sensing device according to one or more embodiments of the present disclosure.

FIG. 3 is a view showing an example of an electronic device including the low power sensing device.

FIG. 4 is a view for explaining enabling and disabling of a sensor and a reference sensor.

FIG. 5 is a view showing operation timing of the low power sensing device.

FIG. 6 is a view showing a wave form of a current consumed by the low power sensing device during a full operation mode.

FIG. 7 is a view showing a wave form of a current consumed by the low power sensing device during a dynamical control mode.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

An aspect of the present disclosure may provide a low power sensing device which may reduce power consumption by controlling on-off switching of each sensor based on a sampling rate for recognizing a touch switch, and using a controller also dynamically controlling an operating clock frequency, and an electronic device including the same.

[symbol]

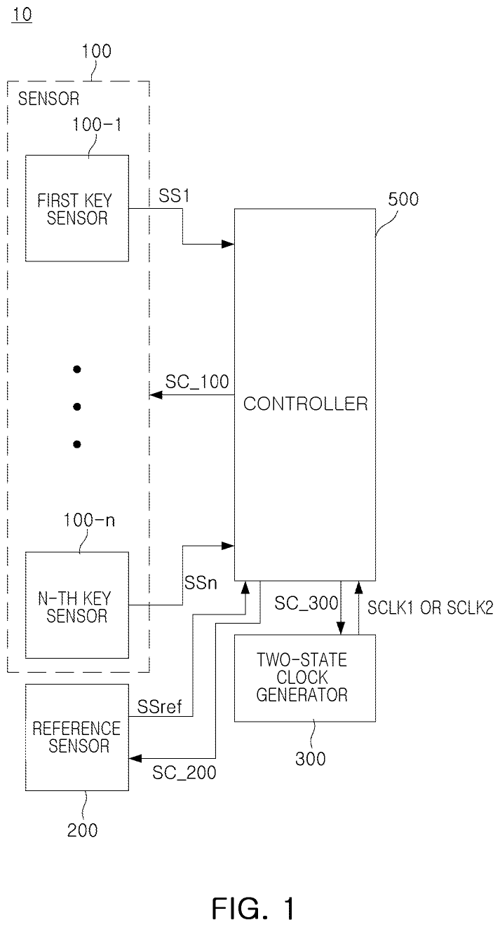

FIG. 1 is a view showing an example of a low power sensing device according to one or more embodiments of the present disclosure.

Referring to FIG. 1, a low power sensing device 10 according to one or more embodiments of the present disclosure may include a sensor 100, a reference sensor 200, a two-state clock generator 300 and a controller 500.

The sensor 100 may include a plurality of key sensors 100-1 to 100-n, generating respective sensing signals by sensing touch or press activity. The plurality of key sensors 100-1 to 100-n may generate and output respective sensing signals SS1 to SSn to the controller 500.

For example, the sensor 100 may include at least two key sensors.

The reference sensor 200 may generate a reference sensing signal SSref. For example, the reference sensor 200 may be used to remove common noise.

The two-state clock generator 300 may generate a first clock signal Sclk1 and a second clock signal Sclk2 having clock frequencies different from each other. The first clock signal Sclk1 may have a frequency set higher than the second clock signal Sclk2. For example, the first clock signal Sclk1 may have a frequency of 10 MHz, and the second clock signal Sclk2 may have a frequency of 5 MHz, and the present disclosure is not limited thereto.

The controller 500 may receive the first clock signal Sclk1 from the two-state clock generator 300 during a first operation mode OM1, and receive the second clock signal Sclk2 from the two-state clock generator 300 during a second operation mode OM2, based on the first operation mode OM1 and the second operation mode OM2 each repeatedly performed for a predetermined time, and may repeatedly control enable operations and disable operations of the sensor 100 and reference sensor 200, based on the first operation mode OM1 and the second operation mode OM2.

The description omits an unnecessary redundant description for components denoted by the same reference numerals and having the same functions in the respective drawings of the present disclosure, and describes differences in the respective drawings.

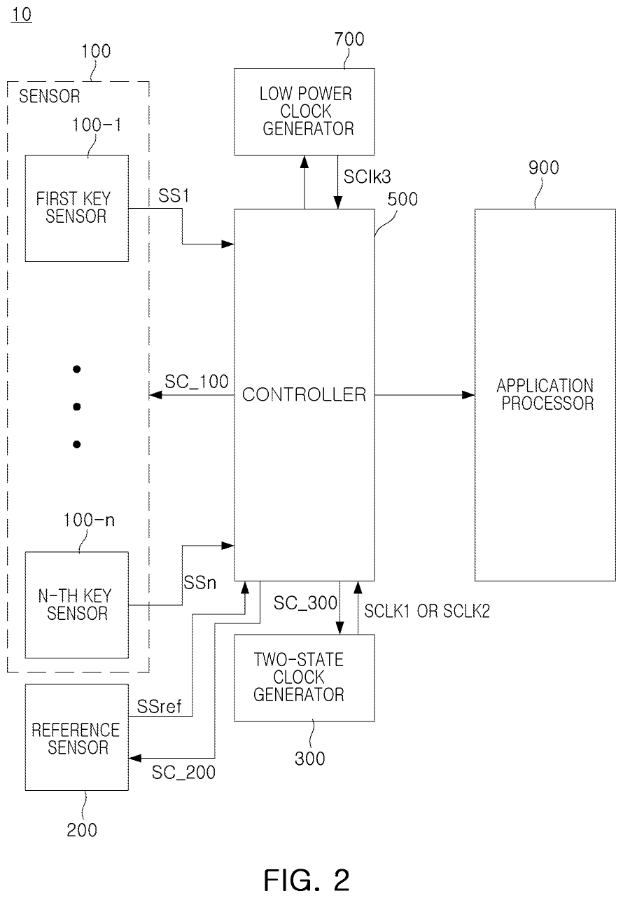

FIG. 2 is a view showing another example of the low power sensing device according to one or more embodiments of the present disclosure.

Referring to FIG. 2, the low power sensing device 10 may further include a low power clock generator 700 in addition to the components shown in FIG. 1.

The low power clock generator 700 may function as a wake-up timer (Interrupt) of the low power sensing device 10 during a sleep mode and as a reference processing timer of a micro central processing unit (MCU), thus generating a low power time clock Sclk3. For example, the controller 500 may wake up from the sleep mode at the predetermined time, based on the low power time clock Sclk3 generated by the low power clock generator 700.

For example, the low power clock generator 700 may function as the wake-up timer by using approximately several KHz of the low power time clock Sclk3, thereby allowing the entire controller 500 to enter a deep sleep or a sleep mode to be in a standby mode.

In this case, the controller 500 may allow each sensor to be changed into the operation mode in minimum time when receiving a signal having a predetermined size or more without separately processing, such as low-pass filtering or averaging data of the key sensor, which is input to the controller 500, in order to process the data faster than an operation of the existing key sensor.

In addition, the controller 500 may provide an application processor 900 with sensing information based on the respective sensing signals SS1 to SSn of the plurality of key sensors 100-1 to 100-n by using the sensor 100, and the application processor 900 may thus perform a predetermined operation based on the sensing information.

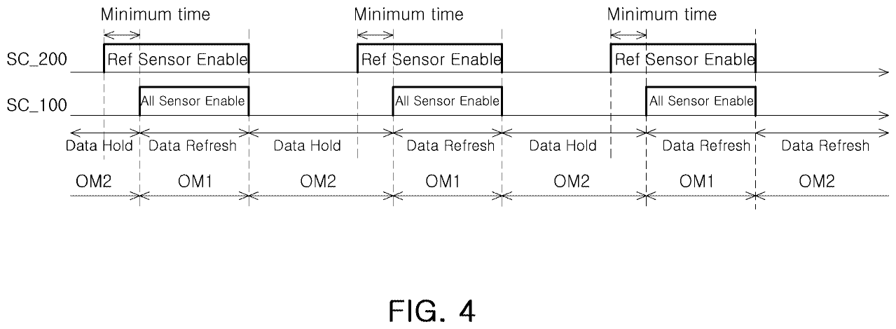

In addition, the controller 500 may control the enable operations of the sensor 100 and the reference sensor 200 during the first operation mode OM1, and the disable operations of the sensor 100 and the reference sensor 200 during the second operation mode OM2, which is described with reference to FIG. 4.

In FIG. 2, the controller 500 may respectively transmit a first control signal SC_100, a second control signal SC_200 and a third control signal SC_300 to the sensor 100, the reference sensor 200 and the two-state clock generator 300, respectively. In addition, the first control signal SC_100, the second control signal SC_200 and the third control signal SC_300 may each be a signal for changing a state of the low power sensing device 10, such as an enable signal for controlling each channel.

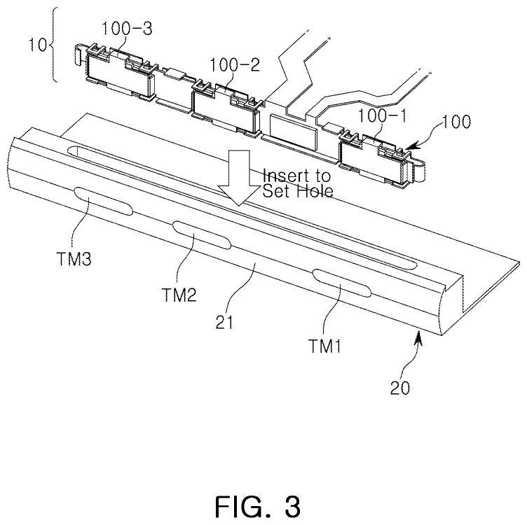

FIG. 3 is a view showing an example of an electronic device including the low power sensing device.

Referring to FIG. 3, an electronic device 20 of the present disclosure may include the low power sensing device 10 described above, and may be a mobile device such as a mobile phone for example.

For example, the electronic device 20 may include a plurality of touch members TM1 to TM3 positioned in a housing 21 formed on a side of the electronic device, and the first key sensor 100-1, the second key sensor 100-2 and the third key sensor 100-3 of the low-power sensing device 10 may be positioned to respectively correspond to the plurality of touch members TM1 to TM3.

One or more embodiments of the present disclosure describe the plurality of touch members as three touch members of the first, second and third touch members TM1 to TM3 as an example, which is provided for convenience of explanation and understanding, and the present disclosure is not limited thereto.

For example, touches on the first touch member TM1, the second touch member TM2 and the third touch member TM3 may each be detected through the first key sensor 100-1, the second key sensor 100-2 and the third key sensor 100-3.

For example, a module including an integrated circuit (IC) may be inserted and mounted in the side or edge of the mobile device such as a mobile phone. Here, the sensor 100 may be applied to an applied product in such a manner that the sensor 100 directly or indirectly interacts with the exposed touch member, thus reacting to an external manipulation.

FIG. 4 is a view for explaining the enabling and disabling of the sensor and the reference sensor.

In FIG. 4, SC_100 may denote the first control signal provided from the controller 500 to the sensor 100, and SC_200 may denote the second control signal provided from the controller 500 to the reference sensor 200.

Referring to FIG. 4, for a stable sensing operation of the low power sensing device 10, the controller 500 may use the first control signal SC_100 and the second control signal SC_200 to control the reference sensor 200 to enter an enabled state before all the sensors included in the sensor 100, or to enter a disabled state simultaneously or later than the plurality of key sensors 100-1 to 100-n of the sensor 100.

For example, the controller 500 may provide the sensor 100 and the reference sensor 200 with the first and second control signals SC_100 and SC_200, respectively. For example, during the first operation mode OM1, the controller 500 may provide the reference sensor 200 with the second control signal SC_200 having a high level earlier than the first control signal SC_100 in order to control the reference sensor 200 to be in the enabled state, and may provide the sensor 100 with the first control signal SC_100 having a high level later than the second control signal SC_200 in order to control the sensor 100 to be in the enabled state. In addition, during the second operation mode OM2, the controller 500 may provide the sensor 100 with the first control signal SC_100 having a low level in order to control the sensor 100 to be in the disabled state, and provide the reference sensor 200 with the second control signal SC_200 having a low level transitioned simultaneously or slightly later than the first control signal SC_100 in order to control the reference sensor 200 to be in the disabled state.

For example, the minimum time in which the second control signal SC_200 has the high level earlier than the first control signal SC_100 may depend on a system environment such as time desired for the system.

In addition, the plurality of key sensors 100-1 to 100-n of the sensor 100 may each perform data refresh based on the first control signal SC_100 of the controller 500, in the enabled state during the first operation mode OM1, and each hold data (or perform data hold) which is output in the enabled state during the first operation mode OM1 from being output in the disabled state during the second operation mode OM2.

The reference sensor 200 may thus be in the enabled state earlier than the plurality of key sensors 100-1 to 100-n of the sensor 100, and in the disabled state simultaneously or later than the plurality of key sensors 100-1 to 100-n of the sensor 100, under the control of the controller 500.

As described above, the present disclosure suggests a technique for reducing power of the controller 500 as well as those of the sensor 100 and the reference sensor 200, based on the first operation mode and the second operation mode.

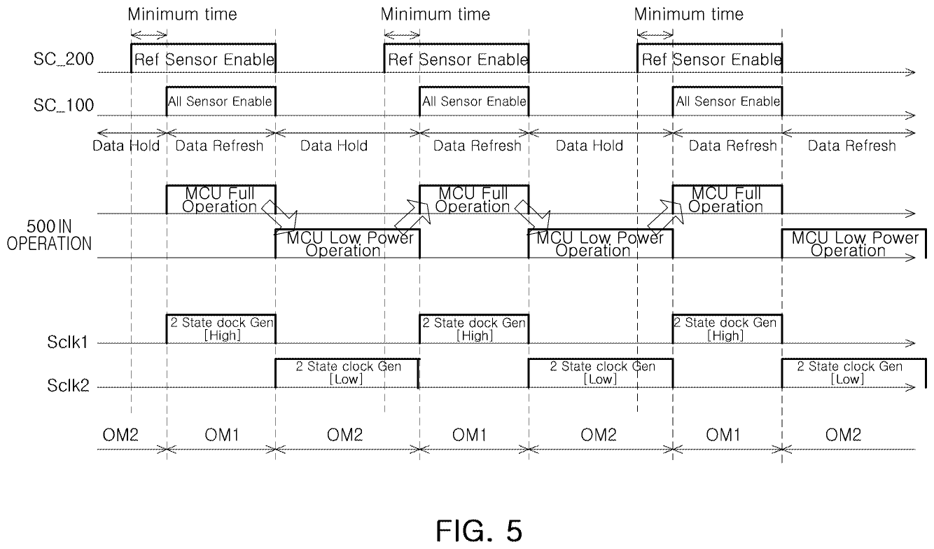

FIG. 5 is a view showing operation timing of the low power sensing device.

FIG. 5 shows the operation timing of the low power sensing device with respect to an operation of the controller 500, synchronized to the first and second control signals SC_100 and SC_200 of FIG. 4, and the first clock signal Sclk1 and the second clock signal Sclk2 generated by the two-state clock generator 300.

Referring to FIG. 5, the controller 500 may perform a full operation in which the controller 500 performs all functions during the first operation mode OM1, and in this case, may receive the first clock signal Sclk1 from the two-state clock generator 300, and control the operations of enabling the sensor 100 and the reference sensor 200.

The controller 500 may perform a low power operation in which the controller 500 performs a predetermined partial operation to save its power during the second operation mode OM2, receive the second clock signal Sclk2 from the two-state clock generator 300, and control the operations of disabling the sensor 100 and the reference sensor 200.

For example, the two-state clock generator 300 may be synchronized with the first operation mode OM1 or the second operation mode OM2 which is repeated under the control of the controller 500 to provide a clock signal suitable for the corresponding operation mode among the first clock signals Sclk1 having a high clock frequency (e.g., 10 MHz) and the second clock signals Sclk2 having a low clock frequency (e.g., 5 MHz).

In addition, the two-state clock generator 300 may change the first clock signal Sclk1 and the second clock signal Sclk2 with each other by using a current control method to have reduced glitches.

For example, to change the clock signals with each other in the two-state clock generator 300, it is possible to use a structure for reducing the frequency from several tens of MHz to several MHz through the current control method rather than a structure of using a D-flip flop.

For example, the two-state clock generator 300 may use tens (e.g., 10 MHz to 50 MHz) and several megahertz (MHz) (e.g., 5 MHz to 1 MHz) as the frequencies of the first clock signal Sclk1 and the second clock signal Sclk2 for an external interface I2C or SPI.

In other words, during the first operation mode OM1 in which the controller performs the full operation, the two-state clock generator 300 may provide the controller 500 with the first clock signal Sclk1 having the high frequency (e.g., 10 MHz). Here, the controller 500 performing the full operation may consume the significantly larger power.

For example, in order to reduce power consumption, during one period including five cycles, the controller 500 may control the sensor 100 to be switched on only for one cycle to two cycles, and may control the sensor 100 to be switched off for the rest time. During the switched-off state, the sensor 100 may hold the data output of each key sensor.

In addition, the controller 500 may simultaneously switch off the reference sensor 200 when switching off the sensor 100. However, the controller 500 may enable the reference sensor 200 earlier than the sensor 100, and may disable the reference sensor 200 simultaneously or later than the sensor 100, thereby preventing the sensor from malfunctioning in its sensing operation.

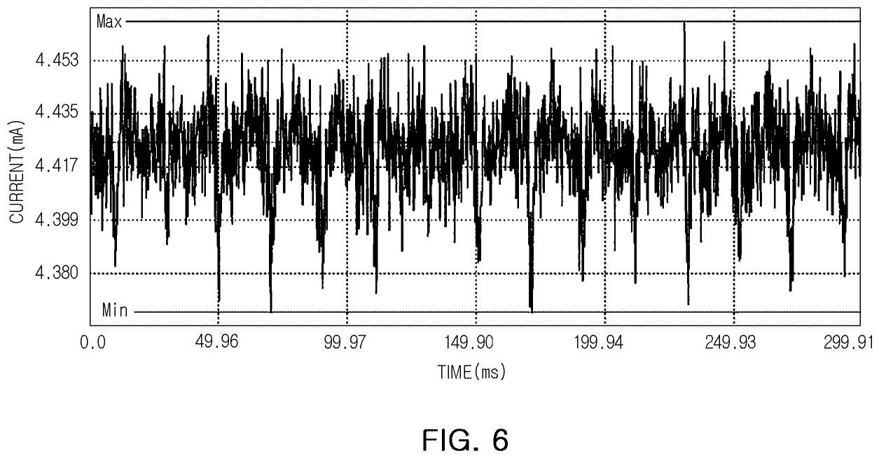

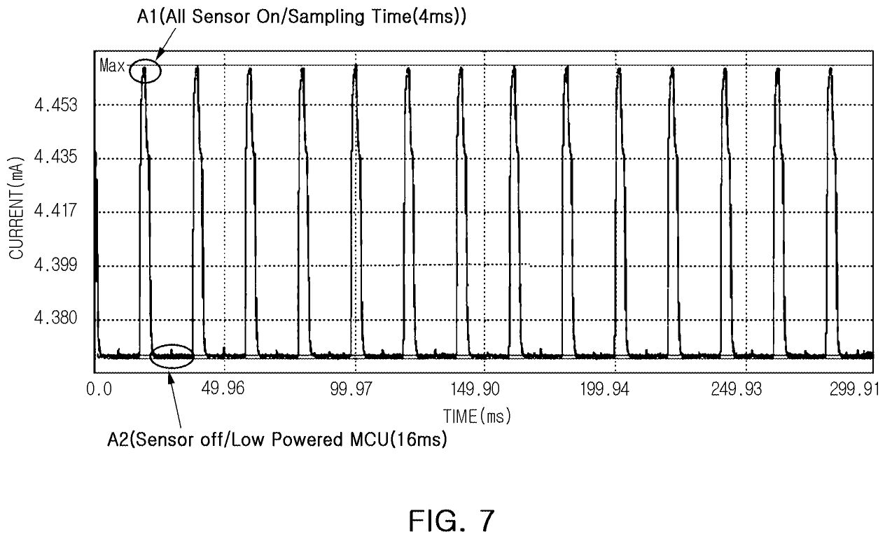

FIG. 6 is a view showing a wave form of a current consumed by the low power sensing device during a full operation mode; and FIG. 7 is a view showing a wave form of a current consumed by the low power sensing device during a dynamical control mode.

Referring to FIG. 6, when performing the full operation, the low power sensing device may consume the current significantly larger than the consumed current shown in FIG. 7.

Referring to FIG. 7, when performing an operation under the dynamic control of the controller, the low power sensing device of the present disclosure may consume the current significantly smaller than the current consumed during the full operation shown in FIG. 6.

Referring to FIGS. 6 and 7, an existing three-button system may have a power reduction amount of about 4 to 5 mA. However, the present disclosure may have a power reduction amount reduced to about 1 mA, thereby securing competitiveness.

Meanwhile, the controller 500 of the low power sensing device according to one or more embodiments of the present disclosure may be implemented by a computing environment in which a processor(for example, a central processing unit (CPU), a graphics processing unit (GPU), a microprocessor, an application specific integrated circuit (ASIC) or a field programmable gate array (FPGA)), a memory (for example, a volatile memory (such as a random access memory (RAM)), a non-volatile memory (such as a read-only memory (ROM) or a flash memory), an input device (for example, a keyboard, a mouse, a pen, a voice input device, a touch input device, an infrared camera or a video input device), an output device (for example, a display, a speaker or a printer), and a communications access (for example, a modem, a network interface card (NIC), an integrated network interface, a radio frequency transmitter/receiver, an infrared port or a universal serial bus (USB) access) are interconnected to one another (for example, a peripheral component interconnect (PCI), a USB, a firmware (IEEE 1394), an optical bus structure or a network).

The computing environment may be implemented by a personal computer, a server computer, a handheld or laptop device, a mobile device (for example, a mobile phone, a personal digital assistants (PDA) or a media player), a multiprocessor system, a consumer electronic device, a mini computer, a mainframe computer, a distributed computing environment including any system or device described above or the like, and the present disclosure is not limited thereto.

As set forth above, one or more embodiments of the present disclosure may reduce power consumption to 20% or less of the existing power consumption by controlling the on-off switching of each sensor based on the sampling rate for recognizing the touch switch, and dynamically controlling the operating clock frequency, thereby making even the controller enter the power saving mode to extremely reduce the power consumption.

As described above, the low power sensing device of the present disclosure may reduce the power consumption, thus being mounted on the gaming phone, may then be mounted on augmented reality (AR) glasses, virtual reality (VR) glasses, a watch or Bluetooth earphones, which pursues the low power consumption, and may thus be used in a variety of electronic devices.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A low power sensing device comprising:
a sensor comprising key sensors configured to generate sensing signals by sensing touch or press activity, respectively;
a reference sensor configured to generate a reference sensing signal;
a two-state clock generator configured to generate a first clock signal and a second clock signal having clock frequencies different from each other; and
a controller configured to
receive the sensing signals and the reference sensing signal,
control enable operations and disable operations of the sensor and the reference sensor based on a first operation mode and a second operation mode each repeatedly performed for a predetermined time,
receive the first clock signal during the first operation mode, and
receive the second clock signal during the second operation mode.

2. The low power sensing device of claim 1, wherein the controller is further configured to control the enable operations during the first operation mode, and the disable operations during the second operation mode.

3. The low power sensing device of claim 1, wherein the controller is further configured to hold data of each of the key sensors that is output in an enabled state during the first operation mode from being output in a disabled state during the second operation mode.

4. The low power sensing device of claim 1, wherein the controller is configured to put the reference sensor in an enabled state before the key sensors, and in a disabled state simultaneously or later than the key sensors.

5. The low power sensing device of claim 1, wherein the controller is configured to synchronize the two-state clock generator with the first operation mode or the second operation mode to alternate between the first clock signal with a high clock frequency and the second clock signal with a low clock frequency.

6. The low power sensing device of claim 1, wherein the two-state clock generator is further configured to alternate between the first clock signal and the second clock signal using a current control method to reduce glitches.

7. The low power sensing device of claim 6, wherein the frequencies of the first clock signal and the second clock signal for an external interface are several megahertz (MHz).

8. The low power sensing device of claim 1, further comprising a low power clock generator configured to function as a wake-up timer in a sleep mode, and generate a low power time clock.

9. An electronic device comprising:
touch members positioned in a housing formed on a side of the electronic device;
a sensor comprising key sensors positioned to correspond to the touch members, and configured to generate sensing signals based on touches or presses input through the corresponding touch members;
a reference sensor configured to generate a reference sensing signal;
a two-state clock generator configured to generate a first clock signal and a second clock signal having clock frequencies different from each other; and
a controller configured to
enable operations and disable operations of the sensor and the reference sensor,
receive the first clock signal during a first operation mode, and
receive the second clock signal during a second operation mode, based on the first operation mode and the second operation mode each repeatedly performed for a predetermined time.

10. The electronic device of claim 9, wherein the controller is further configured to control the enable operations of the sensor and the reference sensor during the first operation mode, and the disable operations of the sensor and the reference sensor during the second operation mode.

11. The electronic device of claim 9, wherein the controller is further configured to hold data of each of the key sensors that is output in an enabled state during the first operation mode from being output in a disabled state during the second operation mode.

12. The electronic device of claim 9, wherein the controller is configured to put the reference sensor in an enabled state earlier than the key sensors of the sensor, and in a disabled state simultaneously or later than the key sensors.

13. The electronic device of claim 9, wherein the controller is configured to synchronize the two-state clock generator with the first operation mode or the second operation mode to alternate between the first clock signal having a high clock frequency and the second clock signal having a low clock frequency.

14. The electronic device of claim 9, wherein the two-state clock generator is further configured to alternate between the first clock signal and the second clock signal using a current control method to reduce glitches.

15. The electronic device of claim 14, wherein the frequencies of the first clock signal and the second clock signal for an external interface are several megahertz (MHz).

16. The electronic device of claim 9, further comprising a low power clock generator configured to function as a wake-up timer in a sleep mode, and generate a low power time clock.
